(19) United States
(12) Patent Application Publication
(10) Pub. No.: US 2011/0048844 A1
(43) Pub. Date: Mar. 3, 2011

(54) ACOUSTIC MATERIAL

(75) Inventor: Maria Papakyriacou, Vienna (AT)

(73) Assignee: NXP B.V., Eindhoven (NL)

(21) Appl. No.: 12/873,782

(22) Filed: Sep. 1, 2010

(30) Foreign Application Priority Data
Sep. 1, 2009 (EP) 09169178.2

(51) Int. Cl. E04B 1/82; H05K 5/00

(52) U.S. Cl. 181/151; 181/199; 181/286

(57) ABSTRACT

An acoustic material is intended to be mounted behind a loudspeaker 8 to decrease the resonant frequency and/or to reduce the back volume. The acoustic material includes a woven or non-woven fabric which supports highly porous particles or fibers such as particles of carbon black. The woven or non-woven is thin and light to avoid damping sound, whilst still being capable of retaining the porous material. The use of a flexible acoustic material allows the material to be more easily included with loudspeakers in portable mobile devices.

This application claims priority to EPO Patent Application No. 09169178.2 filed on Sep. 1, 2009, the entire disclosure of which is herein expressly incorporated by reference.

The invention relates to an acoustic material, a loudspeaker arrangement using the acoustic material and a mobile device including a loudspeaker and the acoustic material.

Conventional loudspeakers generate sound by electrically actuating a diaphragm. A cabinet or enclosure is used to eliminate the sound being emitted rearwardly from the diaphragm and to load the diaphragm. Large cabinets are however unsuitable in some applications, such as mobile devices such as mobile telephones, laptops and the like. Small cabinets can however give rise to difficulties, especially resonant effects.

Highly porous powders and fibres may be used behind loudspeaker diaphragms to reduce the resonant frequency of loudspeakers and/or to reduce the back volume. However, the use of such powders and fibers gives rise to a number of problems.

In the case that the porous material is electrically conductive, for example activated carbon, the powders or fibers can cause short circuits in the surrounding electrical circuits. Further, in the case of a noble porous material, contact with the metal housing can give rise to a battery effect which degrades the metal housing.

Loose powder or fibre debris can clog acoustic units and block air paths. Sound waves can displace loose powder and reduce the effect.

For these reasons, the porous materials have to be contained in a rigid and fixed enclosure, which cannot be too small. This can give rise to problems especially in the design of mobile telephones including such loudspeakers in view of the very small size of modern mobile telephones and consequent shortage of space.

WO02/062099 proposes a sintered porous polymeric material as an acoustic absorbent to separate the air space behind a loudspeaker membrane. Low frequencies are damped by the sintered porous material.

EP 2 003 924 teaches use of a porous material in a speaker system. In one embodiment, the porous material is contained in packing components made of non-woven.

U.S. Pat. No. 4,657,108 relates to a loudspeaker using activated charcoal granules.

According to a first aspect of invention, there is provided a porous material according to claim 1.

By containing the porous material in a fabric efficient acoustic performance can be achieved using a non-rigid, thin structure that can readily be incorporated in mobile devices in a way that is both flexible and space-saving.

The fabric has a specific weight of no more than 25 g/m² and a thickness of no more than 70 μm. This reduces the sound-absorbing effects of the fabric. Note that unlike the sintered porous polymeric material proposed in WO02/062099 the intention in the present case is not to function as a sound absorber, but to increase the size of the effective rear cavity of a loudspeaker and hence reduce the resonant frequency, using the increased path length of air in the porous material.

The hole size of the fabric may be at least 1 nm but not more than 100 μm. A hole size of 1 nm is sufficient to allow air to pass through, but the holes should not be larger than 100 μm to ensure that the porous material is effectively contained in the fabric.

The fabric may be made of hydrophobic fibres. This reduces corrosion when the acoustic material is incorporated in a metal housing. The fibres may be of plastics material.

The porous material may be activated carbon, which has a good porosity for its size and which is relatively inexpensive.

In another aspect, the invention relates to a loudspeaker arrangement having a loudspeaker diaphragm and the acoustic material mounted behind the loudspeaker.

The invention is of particular use in a mobile device with a metal casing. The flexible nature of the fabric allows efficient use of space.

For a better understanding of the invention, embodiments will now be described, purely by way of example, with reference to the accompanying drawings, in which:

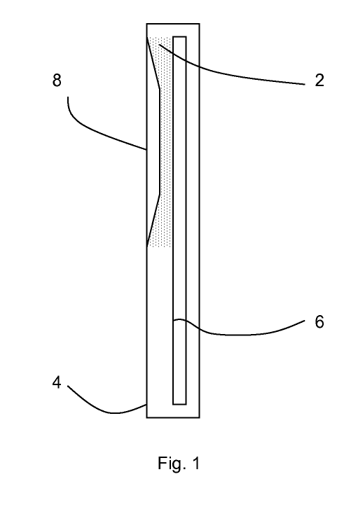

FIG. 1 illustrates a loudspeaker arrangement according to the invention.

Referring to FIG. 1, a mobile device according to an embodiment of the invention includes an acoustic material 2 which will be described in more detail below mounted behind loudspeaker 8 within housing 4. Thus, the acousticmaterial is mounted, in this embodiment between loudspeaker 8 and circuit board 6.

The acoustic material 2 is intended to increase the size of the effective cavity behind the loudspeaker 8 and hence decrease the resonant frequency of the loudspeaker. The acoustic material should have minimal sound damping and good penetrability to air.

The acoustic material is formed of two components. The support component is a woven or non-woven fabric made of hydrophobic material, here plastics material. To avoid increasing the resonant frequency, and to avoid reducing the sound pressure level (SPL) generated by the loudspeaker by damping (acoustic air friction) in the filter, the filter is neither too dense nor too thick.

In this embodiment, the fabric is light, no more than 25 g/m², preferably no more than 20 g/m², and relatively thin, no more than 70 μm thick, preferably no more than 50 μm thick. These thicknesses are measured with the fabric not compressed or under load. The hole size in the fabric is at least 1 nm, to allow air to penetrate freely, and not more than 100 μm, to provide an effective barrier to the porous material described below to prevent escape to the surroundings. The fabric may also be referred to as a “filter”.

The fabric supports the acoustically active porous material, which in the specific example is activated carbon. The highly porous material reduces the resonant frequency of the loudspeaker.

Alternative highly porous material includes different powders or fibers. Other examples include Silica, SiO2, Alumina Al2O3, Zirconia ZrO3, Magnesia (MgO), carbon nanotubes, fullerene etc.

The acoustic material according to the invention is capable of containing the acoustically active porous material, avoiding escape of the powder to elsewhere within the device. This can avoid short circuits on the circuit board 6.

Moreover, the acoustic material is highly flexible. This makes it very easy to incorporate into circuit designs; the material can be applied in the free space between different components on the circuit board.

Measurements have been made of a number of examples using a cellulose based non-woven of varying thickness and area density containing activated charcoal density in a loudspeaker having a cavity. The results are presented in table 1.

The resonant frequency of the cavity was approximately 1000 Hz without the use of the example acoustic materials. Using activated charcoal, but no fabric, this resonant frequency was reduced by approximately 200 Hz, to 800 Hz corresponding to a larger cavity.

When an acoustic material according to the examples with activated charcoal contained in a fabric was used, the resonant frequency changed compared with the resonance frequency using activated charcoal only. The difference between the resonance frequency using activated charcoal and the resonance frequency using the example is presented in table 1 as Δres[Hz]—the positive values in the table mean that the acoustic materials have a slightly higher resonant frequency than when using activated charcoal alone.

The reduction in sound pressure levels, the handling and machinablility properties and the barrier properties were also determined

| Example | A | B | C | D | E | F |
|---|---|---|---|---|---|---|
| Thickness [mm] | 0.06 | 0.11 | 0.11 | 0.04 | 0.04 | 0.06 |
| Weight [g/m²] | | 35 | 35 | 13 | 18 | 22/23 |
| Δres[Hz] | 16 | 33 | 29 | 13 | 9 | 20 |
| Reduction SPL | almost | not | not | absent | absent | not |
| | negligible | negligible | negligible | | | negligible |
| Handling/ | easy | difficult | difficult | easy | easy | easy |
| Machinability | | | | | | |
| barrier against | yes | yes | yes | yes | yes | yes |
| wear debris | | | | | | |

It will be noted from the small Δres[Hz] values that the change in resonant frequency using the examples is very similar to that using activated charcoal alone, without the fabric. Thus, the use of thin low density fabric in the examples to contain the activated charcoal gives very similar results to activated charcoal alone, and with much greater ease of handling, machinability and use as a barrier.

It will be seen that particularly good results were obtained with area densities below 25 or perhaps 20 g/m² and thickness below about 0.07 mm, 70 μm, with the best results being from thicknesses around 0.04 mm, 40 μm.

Although these examples use a cellulose based non-woven, improved resistance to atmospheric moisture can be obtained using plastics materials for the fabric, especially hydrophobic plastics.

1. An acoustic material comprising:
a flexible woven or non-woven fabric;
a porous material contained by the fabric, the porous material being made up of particles or fibres;
characterised in that the porous material is incorporated in the fabric and the fabric has a specific weight of no more than 25 g/m² and a thickness of no more than 70 μm.

2. An acoustic material according to claim 1 wherein the hole size of the fabric is at least 1 nm but not more than 100 μm.

3. An acoustic material according to claim 1 wherein the fabric is made of hydrophobic fibres.

4. An acoustic material according to claim 1 wherein the porous material is activated carbon.

5. An acoustic material according to claim 1 wherein the fibres of the fabric are of plastics material.

6. A loudspeaker arrangement, comprising:
a loudspeaker cavity; and
an acoustic material according to claim 1 mounted in the loudspeaker cavity.

7. A mobile device, comprising:
a housing;
a loudspeaker diaphragm mounted in the housing; and
an acoustic material according to claim 1 mounted behind the loudspeaker diaphragm in the housing.
